(19) United States
(12) Patent Application Publication
(10) Pub. No.: US 2024/0058898 A1
(43) Pub. Date: Feb. 22, 2024

(54) WAFER PROCESSING METHOD

(71) Applicant: DISCO CORPORATION, Tokyo (JP)

(72) Inventors: Masakazu KOBAYASHI, Tokyo (JP); Hiroyuki TAKAHASHI, Tokyo (JP)

(21) Appl. No.: 18/362,469

(22) Filed: Jul. 31, 2023

(30) Foreign Application Priority Data
Aug. 19, 2022 (JP) 2022-130989

(51) Int. Cl. B23K 26/364; H01L 21/3065; B23K 26/00; B23K 26/16

(52) U.S. Cl. CPC B23K 26/364; H01L 21/3065; B23K 26/009; B23K 26/16; B23K 2101/40

(57) ABSTRACT

After first processed grooves are formed by application of a laser beam to a functional layer of a wafer, first damaged regions generated in the functional layer are removed by plasma etching. As a result, damages formed by application of a laser beam can favorably be removed from the functional layer. Consequently, the flexural strength of chips formed by the wafer being divided can be increased.

### BACKGROUND OF THE INVENTION

### Field of the Invention

The present invention relates to a processing method for a wafer including a functional layer.

### Description of the Related Art

There are wafers in which a functional layer is formed on a face side of a base layer such as an Si substrate. The functional layer has a stacked structure in which a nitride film, an oxide film, an inter-layer dielectric film such as a polyimide film, devices, wires, and the like are stacked. When a cutting blade is used to form processed grooves along projected dicing lines in the functional layer of such a wafer, the processing load increases, making it more likely that the films peel off. Hence, as described in Japanese Patent Laid-open No. 2005-064231, it is typical to form laser processed grooves by application of a laser beam to the functional layer.

### SUMMARY OF THE INVENTION

However, when a functional layer is to be processed by application of a laser beam, damages may be caused to the functional layer due to influence of heat. In the past, there has been developed a method of removing damages caused by laser processing, for a base layer such as an Si substrate. Yet, in recent years, in relation to the increased thickness of the functional layer, it has been found that the damages caused to the functional layer, on which no attention has been focused in the past, have an impact on the flexural strength of the chips obtained when the wafer is divided into chips.

It is accordingly an object of the present invention to provide a wafer processing method that is less likely to leave behind damages.

In accordance with an aspect of the present invention, there is provided a wafer processing method for processing a wafer in which a functional layer is stacked on a base layer, the wafer processing method including a functional layer processing step of applying a laser beam to the functional layer and forming first processed grooves, and a functional layer damage removing step of, after the functional layer processing step is carried out, performing plasma etching on face sides of the first processed grooves and removing damages formed in the functional layer processing step.

Preferably, the functional layer is covered with a protective film, and the functional layer processing step removes the protective film covering an edge of each of the first processed grooves by application of the laser beam and exposes the functional layer. Preferably, the wafer processing method further includes a base layer processing step of forming second processed grooves in the base layer.

Preferably, the base layer processing step includes forming the second processed grooves by application of a laser beam to the base layer, and the wafer processing method further includes a base layer damage removing step of, after the base layer processing step is carried out, performing plasma etching on face sides of the second processed grooves formed in the base layer and removing damages formed in the base layer processing step.

Preferably, the base layer processing step includes forming the second processed grooves by application of a laser beam to the base layer, and the wafer processing method further includes a processing swarf removing step of, after the base layer processing step is carried out but before the functional layer damage removing step is performed, applying a laser beam weaker in output power than the laser beam used in the base layer processing step to at least either the first processed grooves or the second processed grooves and subliming and removing processing swarf that has adhered to the grooves.

According to the present invention, after the first processed grooves are formed by application of a laser beam to the functional layer of the wafer, the damages generated in the functional layer are removed by plasma etching. This allows the damages formed by application of a laser beam to be removed favorably from the functional layer. Consequently, the flexural strength of chips formed by the wafer being divided can be increased.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a frame unit including a wafer;

FIG. 2 is a block diagram illustrating a configuration of a processing system;

FIG. 3 is a perspective view illustrating a configuration of a laser processing apparatus;

FIG. 4 is a cross sectional view illustrating a configuration of a plasma processing apparatus;

FIG. 5 is a partial cross-sectional side view illustrating a configuration of a cleaning apparatus;

FIG. 6 is a cross sectional view illustrating a structure of the wafer;

FIG. 7 is a cross sectional view illustrating a protective film forming step;

FIG. 8 is a cross sectional view illustrating laser beam application performed by the laser processing apparatus;

FIGS. 9A to 9D are cross sectional views illustrating a processing method according to a first embodiment of the present invention;

FIG. 10 is a side elevational view illustrating a configuration of a grinding apparatus;

FIGS. 11A to 11F are cross sectional views illustrating the processing method according to a second embodiment of the present invention;

FIGS. 12A to 12C are cross sectional views illustrating another processing method according to the second embodiment; and

FIGS. 13A to 13E are cross sectional views illustrating the processing method according to a third embodiment of the present invention.

### DETAILED DESCRIPTION OF THE PREFERRED EMBODIMENTS

### First Embodiment

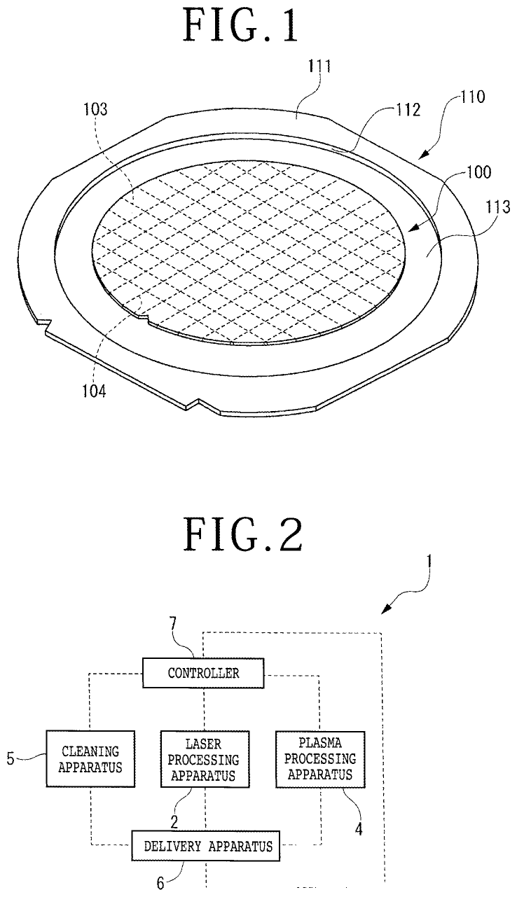

In the present embodiment, such a wafer 100 as illustrated in FIG. 1 is used as a workpiece. The wafer 100 has a circular plate shape and has, on its face side, a plurality of first projected dicing lines 103 that extend in a first direction and a plurality of second projected dicing lines 104 that extend in a second direction perpendicular to the first direction. In areas demarcated by these first projected dicing lines 103 and second projected dicing lines 104, unillustrated devices are formed, for example.

In the present embodiment, as illustrated in FIG. 1, the wafer 100 is handled in a state of being included in a frame unit 110. The frame unit 110 is formed by an annular frame 111 and the wafer 100 being integrated by a dicing tape 113. The annular frame 111 has an opening 112 that can house the wafer 100, and the wafer 100 is positioned in the opening 112 of the annular frame 111.

In the present embodiment, the wafer 100 is processed in a processing system 1 illustrated in FIG. 2, in a state of being included in the frame unit 110 described above.

The processing system 1 illustrated in FIG. 2 is a system for processing the wafer 100 and includes a laser processing apparatus 2 for performing laser processing on the wafer 100, a plasma processing apparatus 4 for performing plasma etching on the wafer 100, a cleaning apparatus 5 for cleaning the wafer 100, a delivery apparatus 6 for delivering the wafer 100 between the abovementioned apparatuses, and a controller 7 for controlling these apparatuses.

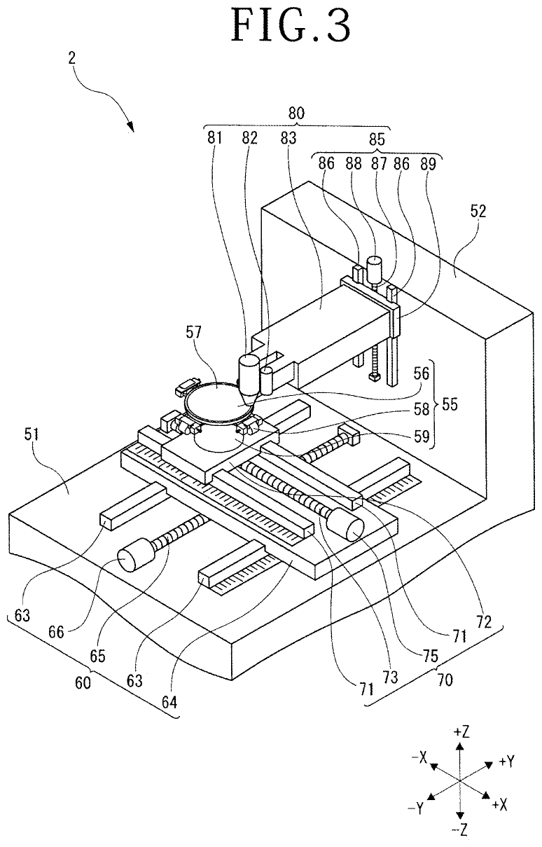

First, a configuration of the laser processing apparatus 2 will be described. As illustrated in FIG. 3, the laser processing apparatus 2 includes a rectangular parallelepiped base 51 and an upstanding wall 52 erected from one end of the base 51.

Provided on an upper surface of the base 51 are a holding unit 55 including a holding table 56, a Y-axis moving mechanism 60 that moves the holding table 56 in a Y-axis direction which is an indexing feed direction, and an X-axis moving mechanism 70 that moves the holding table 56 in an X-axis direction which is a processing feed direction. The holding table 56 includes a holding surface 57 for holding the wafer 100.

The Y-axis moving mechanism 60 moves the holding table 56 in the Y-axis direction parallel to the holding surface 57, with respect to a laser beam application mechanism 80. The Y-axis moving mechanism 60 includes a pair of guide rails 63 extending in the Y-axis direction, a Y-axis table 64 placed on the guide rails 63, a ball screw 65 extending in parallel to the guide rails 63, and a driving motor 66 that rotates the ball screw 65.

The pair of guide rails 63 are disposed on the upper surface of the base 51 in parallel to the Y-axis direction. The Y-axis table 64 is installed on the pair of guide rails 63 in a slidable manner along the guide rails 63. On the Y-axis table 64, the X-axis moving mechanism 70 and the holding unit 55 are placed.

The ball screw 65 is screwed to a nut (not illustrated) that is provided in the Y-axis table 64. The driving motor 66 is coupled to one end of the ball screw 65 and rotationally drives the ball screw 65. When the ball screw 65 is rotationally driven, the Y-axis table 64, the X-axis moving mechanism 70, and the holding unit 55 move in the Y-axis direction along the guide rails 63.

The X-axis moving mechanism 70 moves the holding table 56 in the X-axis direction parallel to the holding surface 57, with respect to the laser beam application mechanism 80. The X-axis moving mechanism 70 includes a pair of guide rails 71 extending in the X-axis direction, an X-axis table 72 placed on the guide rails 71, a ball screw 73 extending in parallel to the guide rails 71, and a driving motor 75 that rotates the ball screw 73.

The pair of guide rails 71 are disposed on an upper surface of the Y-axis table 64 in parallel to the X-axis direction. The X-axis table 72 is installed on the pair of guide rails 71 in a slidable manner along the guide rails 71. On the X-axis table 72, the holding unit 55 is placed.

The ball screw 73 is screwed to a nut (not illustrated) that is provided in the X-axis table 72. The driving motor 75 is coupled to one end of the ball screw 73 and rotationally drives the ball screw 73. When the ball screw 73 is rotationally driven, the X-axis table 72 and the holding unit 55 move in the processing feed direction (X-axis direction) along the guide rails 71.

The holding unit 55 is used for holding the wafer 100. In the present embodiment, the wafer 100 is held by the holding unit 55, as the frame unit 110 illustrated in FIG. 1.

The holding unit 55 includes the holding table 56 for holding the wafer 100, four clamps 58 provided around the holding table 56, and a θ table 59 that supports the holding table 56 and rotates the holding table 56 in an XY plane.

The holding table 56 is a member for holding the wafer 100 and is formed to have a circular plate shape. The holding table 56 includes the holding surface 57 made of a porous material. The holding surface 57 can communicate with an unillustrated suction source. The holding table 56 holds under suction the wafer 100 included in the frame unit 110, by the holding surface 57.

The four clamps 58 provided around the holding table 56 clamp and secure the annular frame 111 surrounding the wafer 100 held on the holding table 56.

On a front surface of the upstanding wall 52 of the laser processing apparatus 2, the laser beam application mechanism 80 is provided.

The laser beam application mechanism 80 applies a laser beam to the wafer 100 held on the holding table 56. The laser beam application mechanism 80 includes a processing head (condenser) 81 that applies a laser beam to the wafer 100, a camera 82 that captures an image of the wafer 100, an arm 83 that supports the processing head 81 and the camera 82, and a Z-axis moving mechanism 85 that moves the arm 83 in the Z-axis direction.

The Z-axis moving mechanism 85 includes a pair of guide rails 86 extending in the Z-axis direction, a Z-axis table 89 attached to the guide rails 86, a ball screw 87 extending in parallel to the guide rails 86, and a driving motor 88 that rotates the ball screw 87.

The pair of guide rails 86 are disposed on the front surface of the upstanding wall 52 in parallel to the Z-axis direction. The Z-axis table 89 is installed on the pair of guide rails 86 in a slidable manner along the guide rails 86. To the Z-axis table 89, the arm 83 is attached.

The ball screw 87 is screwed to a nut (not illustrated) that is provided in the Z-axis table 89. The driving motor 88 is coupled to one end of the ball screw 87 and rotationally drives the ball screw 87. When the ball screw 87 is rotationally driven, the Z-axis table 89 and the arm 83 move in the Z-axis direction along the guide rails 86.

The arm 83 is attached to the Z-axis table 89 in such a manner as to protrude in a −Y direction. The processing head 81 is supported on a distal end of the arm 83 in such a manner as to face the holding table 56 of the holding unit 55.

Inside the arm 83 and the processing head 81, an optical system (not illustrated) of the laser beam application mechanism 80, such as a laser beam oscillator and a condenser lens, is disposed. The laser beam application mechanism 80 is configured to apply a laser beam generated by such an optical system from a lower end of the processing head 81 toward the wafer 100 held on the holding table 56.

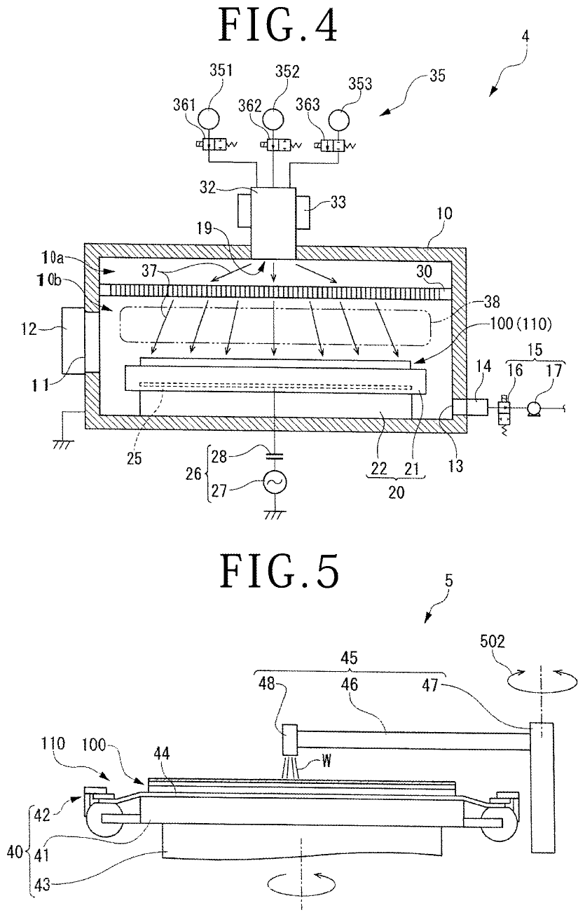

Next, a configuration of the plasma processing apparatus 4 will be described. As illustrated in FIG. 4, the plasma processing apparatus 4 includes a chamber (plasma processing chamber) 10 that has a processing space in its inside. The chamber 10 is, for example, formed of a conductive metal material and is grounded.

In a part of one of the side walls of the chamber 10, there is provided a loading/unloading port 11 for loading and unloading the wafer 100 to and from the inside of the chamber 10. On an outer side of one of the side walls of the chamber 10, there is provided a slide movement type door 12 for closing the loading/unloading port 11.

The door 12 is provided with an opening/closing unit (not illustrated) including an air cylinder and the like. The opening/closing unit, for example, opens or closes the loading/unloading port 11 by causing the door 12 to make a slide movement in an up-down direction.

On a bottom portion side of the side wall of the chamber 10 that is positioned on the opposite side of the side wall where the loading/unloading port 11 is provided, an exhaust port 13 is provided. To the exhaust port 13, an exhaust unit 15 is connected via an exhaust tube 14. The exhaust unit 15 includes an exhaust valve 16, such as a solenoid valve, whose one end of a flow channel is connected to the exhaust tube 14 and an exhaust pump 17 that is connected to the other end of the flow channel of the exhaust valve 16. In the plasma processing apparatus 4, the exhaust unit 15 is used to reduce the pressure inside the chamber 10 to a predetermined pressure, when the wafer 100 is to be etched by gas that has been turned into plasma gas.

In the processing space inside the chamber 10, there is provided a table base 20 for holding the wafer 100. The table base 20 includes a disk portion 21 formed of a conductive material such as metal and a column portion 22 extending downward from a center of a lower surface of the disk portion 21.

On an upper surface side of the disk portion 21, an electrostatic chuck (not illustrated) for holding the wafer 100 is provided. When a voltage is applied to the electrostatic chuck in a state in which the wafer 100 is placed on the disk portion 21, electrostatic force occurs between the electrostatic chuck and the wafer 100. This enables the disk portion 21 to hold the wafer 100.

Note that, in the present embodiment, the wafer 100 is held by the disk portion 21, in the form of the frame unit 110 (in FIG. 4, illustration of the annular frame 111 and the like is omitted). Hence, the disk portion 21 includes clamps (not illustrated) for clamping and securing the annular frame 111 of the frame unit 110. Note that the wafer 100 may be held by the disk portion 21, in a state of being detached from the frame unit 110. Further, in the disk portion 21, there is provided a bias electrode 25 to which a high-frequency voltage is to be applied, in such a manner that the bias electrode 25 is electrically isolated from a plurality of electrodes of the electrostatic chuck. The bias electrode 25 is connected to a high-frequency voltage application unit 26.

The high-frequency voltage application unit 26 includes, for example, a high-frequency power source 27 that is capable of applying a high-frequency voltage to the bias electrode 25 and a blocking capacitor 28 for cutting direct current that is provided between the bias electrode 25 and the high-frequency power source 27.

On the upper side of the table base 20 inside the chamber 10, a plasma diffusion member 30 formed of metal is provided. The plasma diffusion member 30 has a mesh-like region which partitions the processing space inside the chamber 10 into a first area 10a on the upper side and a second area 10b on the lower side.

In the mesh-like region in the plasma diffusion member 30, there are formed a plurality of through openings that spatially connect the first area 10a and the second area 10b. Hence, the plasma diffusion member 30 has a function of dispersing and supplying to the second area 10b gas that has been turned into plasma gas (that is, radical gas, ionized gas, or the like) and supplied to the first area 10a, for example.

On an upper wall of the chamber 10, a gas inlet port 19 is provided. To the gas inlet port 19, there is connected a substantially cylindrical inlet tube 32 in a state of protruding from the upper wall of the chamber 10. Note that the inlet tube 32 is connected to the processing space inside the chamber 10 but is located outside of the chamber 10. The inlet tube 32 is formed of a material (sapphire, crystal, ceramics, or the like) that allows microwaves to transmit therethrough.

Above the inlet tube 32, a gas supply unit 35 is provided. The gas supply unit 35 includes an inert gas supply source 351. The inert gas supply source 351 includes such inert gas as helium (He), argon (Ar), or nitrogen (N₂).

The inert gas supply source 351 is connected to the inlet tube 32 via a first valve 361 and a first flow rate controller (not illustrated) that are provided in the gas supply unit 35, for example. Inert gas is, for example, used as carrier gas for transporting other gas. Yet, inert gas is sometimes used for the purpose of stabilizing electric discharge.

The gas supply unit 35 further includes a fluorine-based gas supply source 352. The fluorine-based gas supply source 352 includes such fluorine-based gas as sulfur hexafluoride (SF₆), tetrafluoromethane (CF₄), or octafluorocyclobutane (C₄F₈).

The fluorine-based gas supply source 352 is connected to the inlet tube 32 via a second valve 362 and a second flow rate controller (not illustrated) that are provided in the gas supply unit 35, for example. The fluorine-based gas is, for example, gas used for etching the wafer 100.

The gas supply unit 35 further includes an oxygen gas supply source 353 that includes oxygen (02) gas. The oxygen gas supply source 353 is connected to the inlet tube 32 via a third valve 363 and a third flow rate controller (not illustrated) that are provided in the gas supply unit 35, for example.

Oxygen gas is, for example, used to control the etching rate of the wafer 100. When active species (fluorine radicals, fluorine ions, etc.) of fluorine atoms that contribute to etching are generated in the process of oxidation of fluorine-containing gas molecules, the etching rate of the wafer 100 sometimes rises.

With the first, second, and third flow rate controllers being adjusted, a plurality of types of gas are supplied at predetermined flow rates from the gas supply unit 35 to the inlet tube 32. Note that the number of gas supply sources, the types of gas, and the flow rate of each gas are changed as appropriate according to the type of the wafer 100, for example.

On a lateral portion of the inlet tube 32, there is provided an applicator 33 that includes a housing formed of a conductive material such as metal, in such a manner as to surround the inlet tube 32. The housing of the applicator 33 includes, for example, a waveguide for applying microwaves generated at a high-frequency generation source such as a magnetron to the inlet tube 32.

The microwaves are electromagnetic waves having a frequency of 300 MHz to 300 GHz (for example, 2.45 GHz). With the microwaves being applied to the plurality of types of gas flowing through the inlet tube 32 via the waveguide of the applicator 33, the plurality of types of gas supplied from the gas supply unit 35 are turned into plasma gas.

The gas turned into plasma gas is supplied to the first area 10a in the processing space inside the chamber 10 from the gas inlet port 19, and is further supplied to the second area 10b in the processing space via the plasma diffusion member 30. In this case, the wafer 100 held by the disk portion 21 is etched by first plasma 37 that is gas that has been turned into plasma gas outside the chamber 10 (remote plasma etching).

However, in a case where microwaves are not applied to the gas supplied from the gas supply unit 35 (that is, the applicator 33 is in an off state), gas that has not been turned into plasma gas is supplied from the gas inlet port 19 to the first area 10a in the processing space.

In this case, with the high-frequency voltage application unit 26 connected to the bias electrode 25 being operated, the gas supplied from the gas inlet port 19 is turned into plasma gas inside the chamber 10. Hence, in this case, the wafer 100 held by the disk portion 21 is etched by second plasma 38 that is gas that has been turned into plasma gas inside the chamber 10 (direct plasma etching).

The plasma processing apparatus having such a configuration is, for example, described in Japanese Patent Laid-open No. 2021-034635.

Next, a configuration of the cleaning apparatus 5 will be described. As illustrated in FIG. 5, the cleaning apparatus 5 includes a holding unit 40 for holding the frame unit 110. The holding unit 40 includes a spinner table 41 for holding the wafer 100, a plurality of clamps 42 provided around the spinner table 41, and a spindle 43 that supports and rotates in the XY plane the spinner table 41.

The spinner table 41 is a member for holding the wafer 100 and includes a holding surface 44 formed of a porous material. The holding surface 44 can communicate with an unillustrated suction source. The spinner table 41 holds under suction the wafer 100 included in the frame unit 110, by the holding surface 44. A plurality of (for example, four) clamps 42 clamp and secure the annular frame 111 surrounding the wafer 100 held by the spinner table 41.

The cleaning apparatus 5 further includes a cleaning water jetting apparatus 45 for jetting cleaning water to the wafer 100 held on the spinner table 41. The cleaning water jetting apparatus 45 includes a water supply pipe 46 that can swing on an upper side of the spinner table 41, a nozzle 48 that is attached to a distal end of the water supply pipe 46, and a rotatable swing shaft 47 that is disposed on the rear end side of the water supply pipe 46. The nozzle 48 is connected to an unillustrated cleaning water supply source. The cleaning water is, for example, purified water.

In the cleaning apparatus 5, when the water supply pipe 46 is swung in association with the rotation of the swing shaft 47 (as indicated by an arrow 502), the nozzle 48 disposed on the distal end of the water supply pipe 46 can, while jetting cleaning water W, move above the wafer 100 held on the rotating spinner table 41. By such jetting of the cleaning water W, the entire surface of the wafer 100 held on the spinner table 41 is cleaned.

The delivery apparatus 6 illustrated in FIG. 2 is capable of holding the frame unit 110 including the wafer 100 by a holding member (not illustrated) such as a robot hand, for example. The delivery apparatus 6 is, for example, capable of loading and unloading the frame unit 110 to and from an unillustrated housing section and delivering the frame unit 110 between the laser processing apparatus 2, the plasma processing apparatus 4, and the cleaning apparatus 5. Note that, without the delivery apparatus 6 being used, an operator may perform delivery of the frame unit 110.

The controller 7 includes a central processing unit (CPU) that performs arithmetic processing according to a control program, a storage medium such as a memory, and the like. The controller 7 controls various members of the processing system 1 and performs processing on the wafer 100.

In the following description, explanation will be given of a processing method for the wafer 100 in the processing system 1 that is controlled by the controller 7.

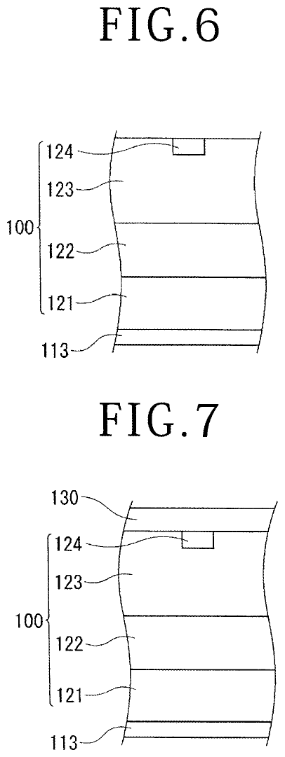

First, a structure of the wafer 100 will be described. As illustrated in FIG. 6, the wafer 100 is formed by a die attach film (DAF) 121 which is an adhesive film, a base layer or a substrate 122 which is the main body of the wafer 100, and a functional layer 123 that are stacked in this order from the dicing tape 113 side.

The base layer 122 is, for example, composed of silicon. The functional layer 123 is, for example, a layer including a nitride film, an oxide film, a low-k film (low dielectric film) such as a polyimide film, devices, and/or a wiring layer. In the present embodiment, a test elementary group (TEG) 124 that is a test pattern is provided on an upper surface of the functional layer 123.

As described above, the processing method according to the present embodiment is a method of processing the wafer 100 in which the functional layer 123 is stacked on the base layer 122. Note that the wafer 100 may not include the TEG 124. Moreover, the wafer 100 may be fixed to the dicing tape 113 that does not include the DAF 121.

### [Protective Film Forming Step (Wafer Preparing Step)]

In the present embodiment, first, an unillustrated protective film forming apparatus forms a protective film 130 composed of water-soluble resin on a face side of the functional layer 123 in the wafer 100, as illustrated in FIG. 7. As a result, the functional layer 123 is covered with the protective film 130. The protective film 130 has, for example, a function of protecting the functional layer 123 from debris generated during processing.

### [Functional Layer Processing Step]

After the protective film 130 is formed on the wafer 100, a functional layer processing step is carried out. In this step, a laser beam is applied to the functional layer 123 of the wafer 100 to form first processed grooves. The functional layer processing step includes a holding step and a laser beam application step that are described below.

### [Holding Step]

In this step, the delivery apparatus 6 or an operator places the wafer 100 included in the frame unit 110 illustrated in FIG. 1 on the holding table 56 of the holding unit 55 included in the laser processing apparatus 2 illustrated in FIG. 3, via the dicing tape 113. Further, the clamps 58 of the holding unit 55 support the annular frame 111 of the frame unit 110. In this state, the controller 7 causes an unillustrated suction source to communicate with the holding surface 57 of the holding table 56, to hold under suction the wafer 100 by the holding surface 57. In this manner, the frame unit 110 including the wafer 100 is held by the holding unit 55 such that the protective film 130 side faces upward.

### [Laser Beam Application Step]

In this step, a laser beam is applied to the functional layer 123 of the wafer 100 along the plurality of first projected dicing lines 103 and second projected dicing lines 104 (see FIG. 1), to form first processed grooves.

Specifically, first, the controller 7 controls the θ table 59 of the holding unit 55 illustrated in FIG. 3 and rotates the holding table 56 such that the first projected dicing lines 103 of the wafer 100 held on the holding surface 57 of the holding table 56 become parallel to the X-axis direction. Thereafter, the controller 7 controls the X-axis moving mechanism 70 to dispose the holding unit 55 to a predetermined application start position that is below the processing head 81 of the laser beam application mechanism 80.

Further, the controller 7 controls the Y-axis moving mechanism 60 to dispose one first projected dicing line 103 of the wafer 100 to a position below the processing head 81. Further, the controller 7 controls the Z-axis moving mechanism 85 of the laser beam application mechanism 80 to appropriately adjust the height of the processing head 81.

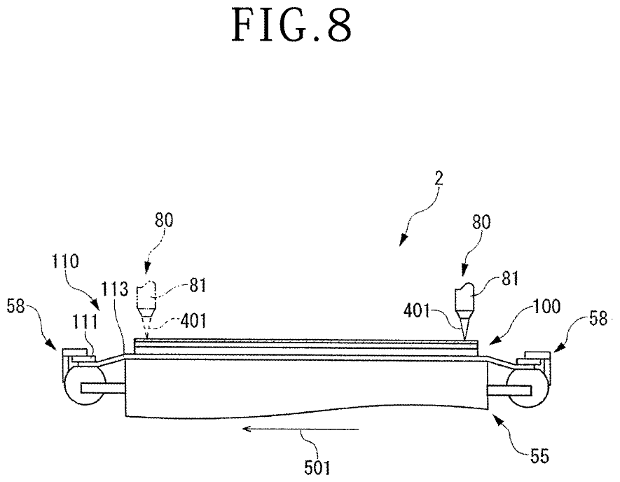

In this state, as illustrated in FIG. 8, the controller 7 controls the optical system of the laser beam application mechanism 80 to generate a laser beam and apply the laser beam denoted by 401 toward the lower side from the processing head 81. The controller 7 also controls the X-axis moving mechanism 70 (see FIG. 3) to move the holding unit 55 holding the frame unit 110, in the X-axis direction as indicated by an arrow 501. As a result, the laser beam 401 output from the processing head 81 is applied along the one first projected dicing line 103. In this step, the wavelength of the laser beam 401 applied from the laser beam application mechanism 80 is a wavelength absorbable by the functional layer 123 of the wafer 100.

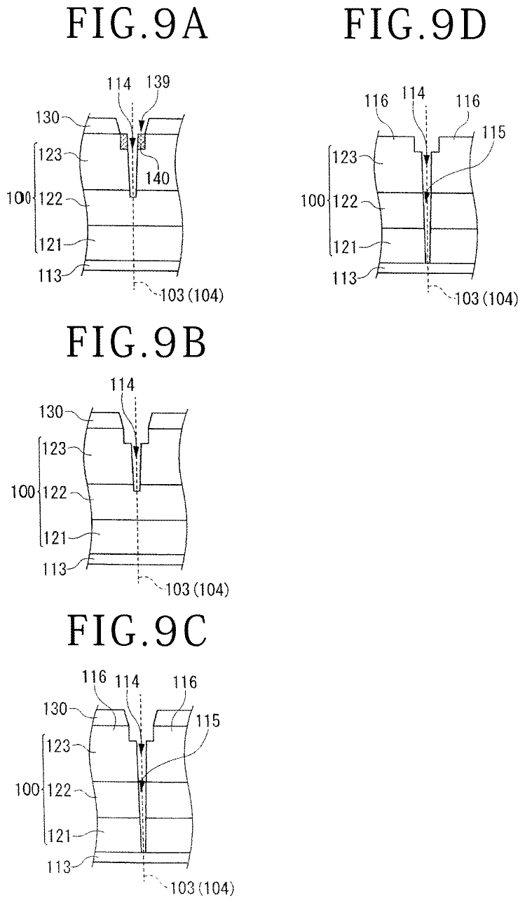

By the laser beam 401 being applied as described above, a first processed groove 114 which is a processed groove (cut groove) extending along the first projected dicing line 103 is formed in the wafer 100 as illustrated in FIG. 9A. In this step, the first processed groove 114 is formed to have a depth that cuts the functional layer 123 and reaches the base layer 122.

Thereafter, the controller 7 stops the application of the laser beam 401 and controls the X-axis moving mechanism 70 to place the holding unit 55 back to the application start position. Then, the controller 7 controls the Y-axis moving mechanism 60 to dispose another first projected dicing line 103 to a position below the processing head 81. Subsequently, the controller 7 applies the laser beam 401 along this first projected dicing line 103 and forms the first processed groove 114. In this manner, the controller 7 applies the laser beam 401 along all of the first projected dicing lines 103 in the wafer 100 and forms the first processed grooves 114.

Next, the controller 7 controls the θ table 59 of the holding unit 55 illustrated in FIG. 3 and rotates the holding table 56 such that the second projected dicing line 104 of the wafer 100 held on the holding surface 57 of the holding table 56 becomes parallel to the X-axis direction.

Thereafter, as in the laser beam application performed along the first projected dicing lines 103, the controller 7 controls the Y-axis moving mechanism 60, the X-axis moving mechanism 70, and the laser beam application mechanism 80 and applies the laser beam 401 along all of the second projected dicing lines 104 to form the first processed grooves 114 illustrated in FIG. 9A.

Note that, in this step, the laser beam 401 is applied in such a manner that the protective film 130 covering an edge (upper surface) of the first processed groove 114 is removed by the heat of the laser beam 401. As a result, an exposed region 139 of the functional layer 123 is formed on the face side of the first processed groove 114, as illustrated in FIG. 9A. As described above, the functional layer processing step is performed in such a manner that the protective film 130 covering the edge of the first processed groove 114 is removed by the laser beam 401 and the functional layer 123 is exposed. This is, for example, implemented by adjustment of the output power of the laser beam 401.

Further, in this step, the heat of the laser beam 401 generates, in the functional layer 123, a first damaged region 140 which is a region damaged, as illustrated in FIG. 9A. Since heat generated by a laser beam goes up, the first damaged regions 140 are more likely to be generated near the face side. Yet, depending on the type of the wafer 100, the first damaged regions 140 may be formed over the entire area around the first processed grooves 114 in some cases.

Note that, in the present embodiment, as described above, the exposed region 139 of the functional layer 123 is formed on the face side of the first processed groove 114. Hence, the first damaged region 140 generated in the functional layer 123 is exposed.

### [Functional Layer Damage Removing Step]

In this step, the first damaged regions 140 generated in the functional layer 123 in the functional layer processing step are removed. That is, after the functional layer processing step is carried out, plasma etching is performed on the face sides of the first processed grooves 114, and the first damaged regions 140 which are damages formed in the functional layer processing step are removed.

Specifically, first, the delivery apparatus 6 or the operator delivers the frame unit 110 including the wafer 100 to the plasma processing apparatus 4 illustrated in FIG. 4. Then, the frame unit 110 is placed on the disk portion 21 of the table base 20 such that the protective film 130 side of the wafer 100 faces upward.

Thereafter, the door 12 is closed, and the controller 7 applies a voltage to the electrostatic chuck of the disk portion 21. This leads to the frame unit 110 including the wafer 100 being held by the disk portion 21. Following this, the controller 7 reduces the pressure in the processing space inside the chamber 10 to a predetermined pressure (for example, 50 Pa) by the exhaust unit 15.

Then, the controller 7 controls the gas supply unit 35 to supply predetermined etching gas to the processing space inside the chamber 10 from the gas supply unit 35. This etching gas is gas that includes at least any one of CF₄, argon, C₄F₈, or oxygen, and is etching gas (first etching gas) that can generate plasma that is suitable for removing the first damaged regions 140 of the functional layer 123.

Further, the controller 7 operates the high-frequency voltage application unit 26 to turn the first etching gas into plasma gas. As a result, the wafer 100 is subjected to plasma etching (direct plasma etching) by the second plasma 38.

Consequently, the face side of the first processed groove 114 in the functional layer 123 of the wafer 100 is subjected to plasma etching, and as illustrated in FIG. 9B, the first damaged region 140 formed in the functional layer 123 is removed. Note that the face side of the first processed groove 114 includes a side surface and an upper surface of the first processed groove 114.

Note that, in this instance, the controller 7 may turn the first etching gas into plasma gas with use of the applicator 33 and the plasma diffusion member 30 and perform remote plasma etching with the first plasma 37, instead of performing direct plasma etching.

### [Base Layer Processing Step]

In this step, second processed grooves are formed in the base layer 122 of the wafer 100. The base layer processing step includes the holding step and the laser beam application step that are described below, similarly to the functional layer processing step.

### [Holding Step]

In this step, as in the holding step of the functional layer processing step described above, the delivery apparatus 6 or the operator places the frame unit 110 including the wafer 100 on the holding table 56 of the holding unit 55 included in the laser processing apparatus 2 illustrated in FIG. 3. Then, under the control of the controller 7, the frame unit 110 is held by the holding unit 55 such that the protective film 130 side of the wafer 100 faces upward.

### [Laser Beam Application Step]

In this step, a laser beam is applied to the base layer 122 of the wafer 100 along the first processed grooves 114, to form second processed grooves 115 as illustrated in FIG. 9C.

In the functional layer 123 of the wafer 100, a plurality of first processed grooves 114 are formed in a grid pattern. As in the laser beam application step of the functional layer processing step described above, the controller 7 controls the θ table 59, the Z-axis moving mechanism 85, the Y-axis moving mechanism 60, the X-axis moving mechanism 70, and the laser beam application mechanism 80 to apply a laser beam along all of the first processed grooves 114 and form the second processed grooves 115 illustrated in FIG. 9C.

The wavelength of the laser beam applied in this step is a wavelength absorbable by the base layer 122 of the wafer 100. Further, in this step, the second processed grooves 115 are formed to have a depth that cuts the base layer 122 and the DAF 121, that is, a depth that divides the wafer 100. Accordingly, this step divides the wafer 100 and manufactures a plurality of chips 116. Note that the DAF 121 may be divided not in the base layer processing step but in a subsequent step in which the dicing tape 113 is expanded. Further, in a case where the DAF 121 is not provided, the second processed grooves 115 are formed to have a depth that cuts into the dicing tape 113, so that the wafer 100 is divided and a plurality of chips 116 are manufactured.

### [Protective Film Cleaning Step]

In this step, the protective film 130 is removed from the wafer 100. Specifically, the delivery apparatus 6 or the operator delivers the frame unit 110 including the wafer 100 to the cleaning apparatus 5 illustrated in FIG. 5, and places the frame unit 110 on the spinner table 41 of the holding unit 40 in such a manner that the protective film 130 side faces upward.

Thereafter, the controller 7 supports the annular frame 111 of the frame unit 110 by the clamps 42 of the holding unit 40 and holds the wafer 100 under suction by the spinner table 41.

Further, the controller 7 controls the cleaning water jetting apparatus 45 and jets the cleaning water W to the entire surface of the wafer 100 held on the spinner table 41, while rotating the spinner table 41 by the spindle 43. As a result, the protective film 130 composed of water-soluble resin is removed from the wafer 100 as illustrated in FIG. 9D.

As described above, in the present embodiment, a laser beam is applied to the functional layer 123 of the wafer 100 and the first processed grooves 114 are formed, after which the first damaged regions 140 generated in the functional layer 123 are removed by plasma etching (functional layer damage removing step). This allows damages formed by application of a laser beam to be removed favorably from the functional layer 123. Consequently, the flexural strength of the chips 116 formed by the wafer 100 being divided can be increased.

Note that the protective film 130 is resistant to plasma etching. Hence, when the edge of the first processed groove 114 is covered with the protective film 130, damages are less likely to be removed. In this regard, in the functional layer processing step of the present embodiment, the protective film 130 covering the edge of the first processed groove 114 is removed by the processing heat generated by the laser beam, and the first damaged region 140 of the functional layer 123 is exposed. Thus, the first damaged region 140 can be removed by plasma etching performed for a short period of time.

Note that, in the base layer processing step of the present embodiment, the second processed grooves 115 are formed by application of a laser beam with use of the laser processing apparatus 2. In regard to this, in the base layer processing step, an unillustrated cutting apparatus may be used to form the second processed grooves 115 by a rotating cutting blade and manufacture chips 116 by dividing the wafer 100, or plasma processing may be performed to form the second processed grooves 115.

Further, in the base layer processing step of the present embodiment, the second processed grooves 115 are formed to have a depth that divides the wafer 100, and in this step, the wafer 100 is divided, so that a plurality of chips 116 are manufactured.

In regard to this, the second processed grooves 115 to be formed in the base layer processing step may be formed to have a depth that does not divide the wafer 100, for example, a depth that does not cut the DAF 121. In this case, after such shallow second processed grooves 115 are formed, the dicing tape 113 may be expanded to divide the wafer 100 and manufacture the chips 116.

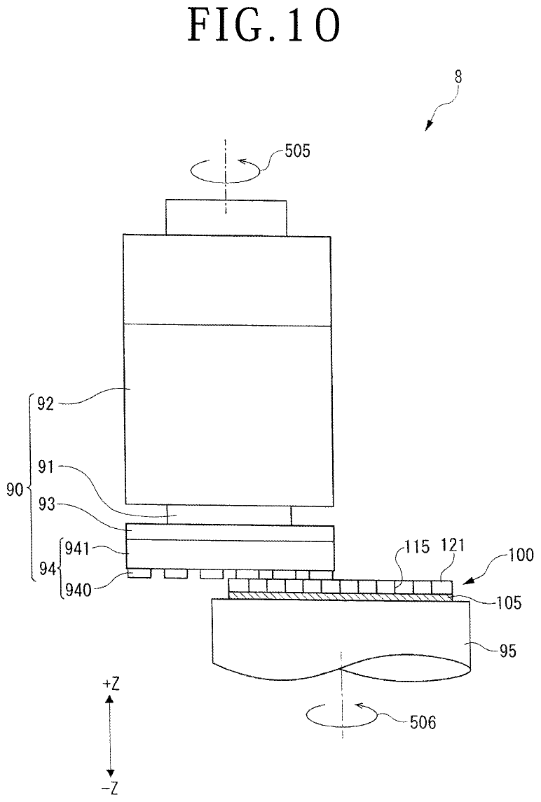

Further, in the case where such shallow second processed grooves 115 are to be formed, the grinding apparatus 8 illustrated in FIG. 10 may be used to divide the wafer 100 and manufacture the chips 116. The grinding apparatus 8 includes a chuck table 95 that holds the wafer 100 under suction and rotates and a grinding mechanism 90 that can move vertically in the Z-axis direction by an unillustrated vertical movement mechanism.

The grinding mechanism 90 includes a spindle 91, a spindle motor 92 that rotates the spindle 91, a mount 93 that is disposed on a lower end of the spindle 91, and a grinding wheel 94 that is attached to the mount 93. The grinding wheel 94 includes a wheel base 941 and a plurality of substantially parallelepiped grindstones 940 annularly arrayed on a lower surface of the wheel base 941.

In a case where the grinding apparatus 8 is to be used, the wafer 100 in which the second processed grooves 115 are formed is, for example, detached from the frame unit 110, and is held under suction on the chuck table 95 via a protective tape 105 such that the DAF 121 faces upward. Thereafter, the controller 7 causes the grindstones 940 to come into contact with the DAF 121 of the wafer 100 and grind the DAF 121, while rotating the spindle 91 and the chuck table 95 of the grinding apparatus 8 (as indicated by arrows 505 and 506). As a result, the second processed grooves 115 are exposed on the upper side, and the wafer 100 is divided, so that the chips 116 are manufactured.

Further, in the base layer processing step, a laser beam having a wavelength transmittable by the base layer 122 may be applied with its focal point positioned inside the base layer 122, and thereafter, the DAF 121 side of the wafer 100 may be ground by the grinding apparatus 8, to divide the wafer 100.

Further, in a case where the base layer processing step includes forming the second processed grooves 115 by application of a laser beam to the base layer 122, that is, in a case where the second processed grooves 115 are to be formed by application of a laser beam in the base layer processing step, damaged regions may sometimes be formed on the face sides of the second processed grooves 115 formed in the base layer 122. In this case, the base layer damage removing step may be performed. In this base layer damage removing step, after the base layer processing step is performed, that is, after the second processed grooves 115 are formed, as in the functional layer damage removing step, the frame unit 110 including the wafer 100 is set in the plasma processing apparatus 4, and the face sides of the second processed grooves 115 formed in the base layer 122 are subjected to plasma etching, so that the damaged regions formed in the base layer processing step are removed. Subjecting also the base layer 122 to plasma etching and removing the damages make it possible to further increase the flexural strength of the chips 116.

Note that, in the base layer damage removing step, etching gas (second etching gas) that can generate plasma that is suitable for removing the damaged regions of the base layer 122 is used as the etching gas. In the base layer damage removing step, for example, the second etching gas including at least any one of helium gas, fluorine-based gas (for example, SF₆), or oxygen gas is used to perform remote plasma etching.

Further, in this case, a processing swarf removing step may further be performed. In this processing swarf removing step, after the base layer processing step using a laser beam by the laser processing apparatus 2 is carried out but before the base layer damage removing step is performed, the laser processing apparatus 2 is continuously used to apply a laser beam weaker in output power than the laser beam used in the base layer processing step to at least either the first processed grooves 114 or the second processed grooves 115, so that the processing swarf adhered to these grooves is sublimed and removed. This makes it possible to easily remove processing swarf that has been generated in the base layer processing step from the first processed grooves 114 and/or the second processed grooves 115. Consequently, it becomes possible to favorably reduce the possibility of processing swarf hindering the plasma etching in the base layer damage removing step.

### Second Embodiment

In the present embodiment, a modification of the processing method illustrated in the first embodiment will be described.

In the method according to the present embodiment, first, the protective film forming step (wafer preparing step) that is similar to the one illustrated in the first embodiment is performed, and thereafter, the functional layer processing step described below is performed.

### [Functional Layer Processing Step]

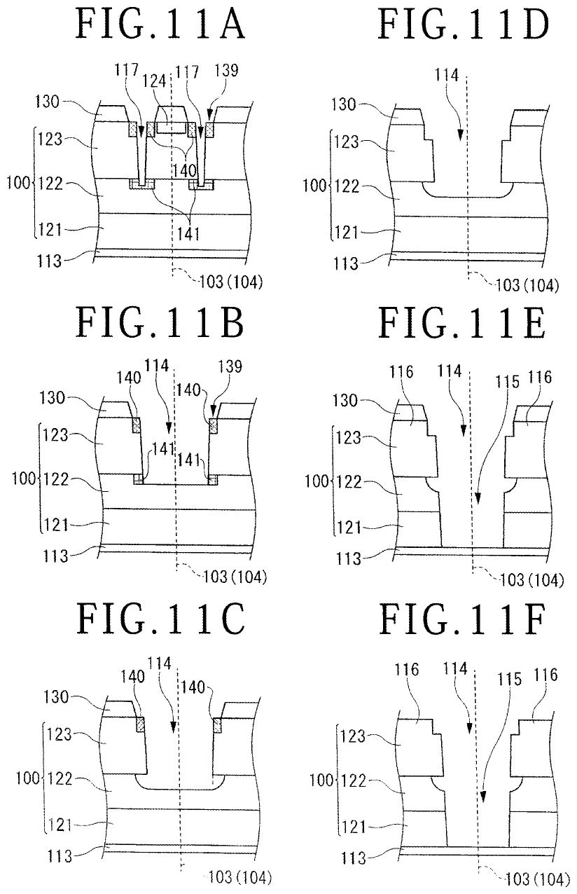

In the functional layer processing step according to the present embodiment, the controller 7 uses the laser processing apparatus 2 to apply a laser beam from the processing head 81 to both sides of each of the first projected dicing lines 103 and the second projected dicing lines 104 in the wafer 100, as illustrated in FIG. 11A. This leads to formation of a pair of processing spare grooves 117 on both sides of each of the first projected dicing lines 103 and the second projected dicing lines 104. The processing spare grooves 117 are formed to have a depth that cuts the functional layer 123 and reaches the base layer 122.

Such a pair of processing spare grooves 117 serve as a shield that prevents the functional layer 123 from peeling off when being processed. That is, the processing spare grooves 117 can prevent the functional layer 123 from peeling off from the face side of the wafer 100.

Further, this processing forms the first damaged regions 140 in the functional layer 123 and second damaged regions 141 in the base layer 122. Note that, this processing also forms the exposed region 139 obtained by removal of the protective film 130 stacked on the upper surface of the functional layer 123.

Further, in the functional layer processing step according to the present embodiment, the controller 7 continuously uses the laser processing apparatus 2 to apply a laser beam to the center of the pair of processing spare grooves 117 along each of the first projected dicing lines 103 and the second projected dicing lines 104. As a result, as illustrated in FIG. 11B, the first processed groove 114 is formed along each of the first projected dicing lines 103 and the second projected dicing lines 104. Note that the wavelength of the laser beam applied in this step is a wavelength absorbable by the functional layer 123.

### [Base Layer Damage Removing Step]

In this step, the second damaged regions 141 generated in the base layer 122 in the functional layer processing step are removed. That is, after the frame unit 110 including the wafer 100 is set in the plasma processing apparatus 4, the controller 7 subjects the face side of the first processed groove 114 to plasma etching. As a result, the second damaged regions 141 formed in the base layer 122 in the functional layer processing step are removed, as illustrated in FIG. 11C.

In this base layer damage removing step, as described above, the second etching gas that can generate plasma that is suitable for removing the second damaged regions 141 formed in the base layer 122 is used.

### [Functional Layer Damage Removing Step]

In this step, the first damaged regions 140 generated in the functional layer 123 in the functional layer processing step are removed. That is, the controller 7 continuously uses the plasma processing apparatus 4 to perform plasma etching on the face side of the first processed groove 114. As a result, the first damaged regions 140 formed in the functional layer 123 in the functional layer processing step are removed, as illustrated in FIG. 11D.

In this functional layer damage removing step, as described above, the first etching gas that can generate plasma that is suitable for removing the first damaged regions 140 formed in the functional layer 123, for example, gas including at least any one of CF₄, argon, C₄F₈, or oxygen, is used. Also in this step, the exposed region 139 is formed in the functional layer 123, so that the first damaged regions 140 can easily be etched.

### [Base Layer Processing Step]

In this step, the second processed grooves 115 are formed in the base layer 122. Specifically, the controller 7 uses the laser processing apparatus 2 to apply a laser beam along all of the first processed grooves 114 in the wafer 100, and forms the second processed groove 115 as illustrated in FIG. 11E. The wavelength of the laser beam applied in this step is a wavelength absorbable by the base layer 122. This step allows, for example, the wafer 100 to be divided and the plurality of chips 116 to be manufactured. In this step, an unillustrated cutting apparatus may be used to form the second processed grooves 115 by a rotating cutting blade, or plasma processing may be performed to form the second processed grooves 115.

### [Protective Film Cleaning Step]

After the base layer processing step, the controller 7 uses the cleaning apparatus 5 to perform a protective film cleaning step similar to the one illustrated in the first embodiment, and removes the protective film 130 from the wafer 100 as illustrated in FIG. 11F.

In the present embodiment, after the first processed grooves 114 are formed, the first damaged regions 140 generated in the functional layer 123 and the second damaged regions 141 generated in the base layer 122 are removed by plasma etching. This allows the damages formed by application of a laser beam to be removed favorably from the functional layer 123 and the base layer 122, so that the flexural strength of the chips 116 formed by the wafer 100 being divided can further favorably be increased.

Further, in the present embodiment, after the functional layer processing step but before the base layer processing step, the base layer damage removing step and the functional layer damage removing step are carried out. In regard to this, if the base layer damage removing step or the functional layer damage removing step is performed after the base layer processing step, processing swarf of the base layer 122 adhering to the first processed grooves 114 and the second processed grooves 115 may hinder etching to be performed in these damage removing steps. Accordingly, as in the present embodiment, performing the base layer damage removing step and the functional layer damage removing step after the functional layer processing step but before the base layer processing step enables etching to proceed in a short period of time in these damage removing steps and the first damaged regions 140 and the second damaged regions 141 to be removed favorably.

Note that the order of performing the base layer damage removing step, the functional layer damage removing step, and the base layer processing step is not limited to the one described above, and can be adjusted as appropriate.

For example, in the present embodiment, the controller 7 may first use the laser processing apparatus 2 to form the processing spare grooves 117 in the wafer 100 as illustrated in FIG. 11A and then use the plasma processing apparatus 4 to perform the base layer damage removing step using the second etching gas and perform plasma etching on the face sides of the processing spare grooves 117.

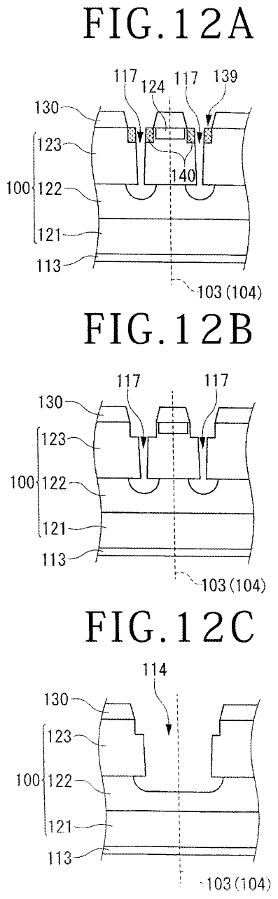

In this case, transition is made from the state illustrated in FIG. 11A to the state illustrated in FIG. 12A in which the second damaged regions 141 are removed from the base layer 122.

Thereafter, the controller 7 continuously uses the plasma processing apparatus 4 to perform the functional layer damage removing step using the first etching gas and performs plasma etching on the face sides of the processing spare grooves 117. As a result, the first damaged regions 140 formed in the functional layer 123 in the functional layer processing step are removed as illustrated in FIG. 12B.

Next, the controller 7 uses the laser processing apparatus 2 to perform the functional layer processing step and apply a laser beam to the center of the pair of processing spare grooves 117 along each of the first projected dicing lines 103 and the second projected dicing lines 104. As a result, the first processed groove 114 is formed along each of the first projected dicing lines 103 and the second projected dicing lines 104 as illustrated in FIG. 12C. Thereafter, the base layer processing step illustrated in FIG. 11E and the protective film cleaning step illustrated in FIG. 11F are performed.

In this manner, removing the first damaged regions 140 and the second damaged regions 141 before the first processed grooves 114 are formed also makes it possible to favorably remove these damages, further allowing the flexural strength of the chips 116 formed by the wafer 100 being divided to be increased.

### Third Embodiment

In the present embodiment, another modification of the processing method illustrated in the first embodiment will be described.

### [Protective Film Forming Step and Functional Layer Processing Step]

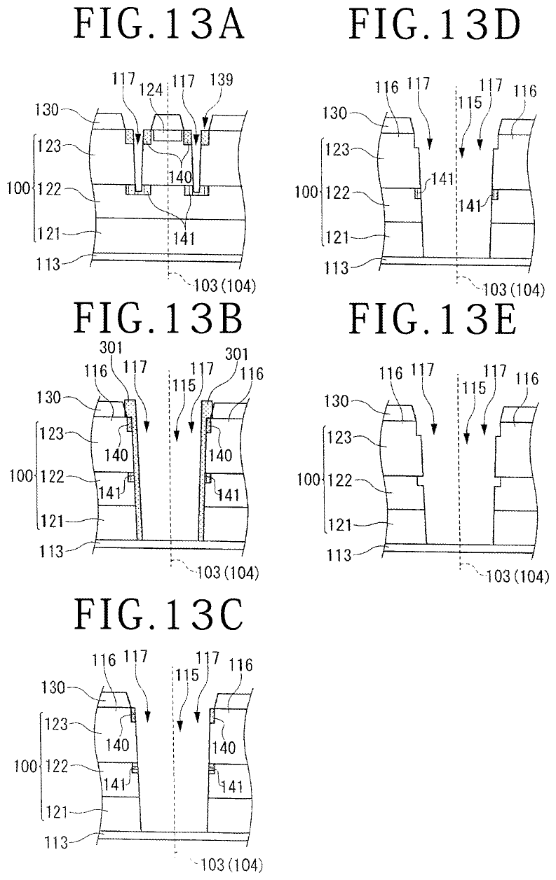

In the method according to the present embodiment, first, a protective film forming step (wafer preparing step) similar to the one illustrated in the first embodiment is performed, and thereafter, the laser processing apparatus 2 is used to perform a functional layer processing step similar to the one illustrated in the second embodiment. As a result, as illustrated in FIG. 13A, a pair of processing spare grooves 117 are formed on both sides of each of the first projected dicing lines 103 and the second projected dicing lines 104 in the wafer 100, to have such a depth that cuts the functional layer 123 and reaches the base layer 122. This processing leads to formation of the first damaged regions 140 in the functional layer 123 and also formation of the second damaged regions 141 in the base layer 122. In the present embodiment, the processing spare grooves 117 function as the first processed grooves.

### [Base Layer Processing Step]

In this step, the second processed grooves 115 are formed in the base layer 122. Specifically, the controller 7 continuously uses the laser processing apparatus 2 to apply a laser beam to the center of the pair of processing spare grooves 117 along each of the first projected dicing lines 103 and the second projected dicing lines 104 in the wafer 100. As a result, the second processed groove 115 is formed along each of the first projected dicing lines 103 and the second projected dicing lines 104, as illustrated in FIG. 13B. The wavelength of the laser beam applied in this step is a wavelength absorbable by the functional layer 123 and the base layer 122.

As described above, the base layer processing step includes forming the second processed grooves 115 by application of a laser beam to the base layer 122. In this step, the second processed grooves 115 are formed to have a depth that cuts the functional layer 123, the base layer 122, and the DAF 121, that is, a depth that divides the wafer 100. Accordingly, this step divides the wafer 100 and manufactures a plurality of chips 116. Note that the DAF 121 may be divided not in the base layer processing step but in a subsequent step in which the dicing tape 113 is expanded. Further, in a case where the DAF 121 is not provided, the second processed grooves 115 are formed to have a depth that cuts into the dicing tape 113, so that the wafer 100 is divided, and a plurality of chips 116 are manufactured. Furthermore, this step causes processing swarf 301 to adhere to the face sides of the processing spare grooves 117 and the second processed groove 115, as illustrated in FIG. 13B.

### [Processing Swarf Removing Step]

In this processing swarf removing step, the controller 7 continuously uses the laser processing apparatus 2 to apply, after the base layer processing step is carried out but before the functional layer damage removing step is performed, a laser beam weaker in output power than the laser beam used in the base layer processing step to at least either the processing spare grooves 117 (first processed grooves) or the second processed grooves 115 and sublime and remove the processing swarf that has adhered to these grooves. In the present embodiment, the controller 7 applies a laser beam weaker in output power than the laser beam applied in the base layer processing step to the processing spare grooves 117 and the second processed grooves 115 to sublime and remove the processing swarf 301 that has adhered to the grooves. As a result, the processing swarf 301 that has been generated in the base layer processing step can be removed from the processing spare grooves 117 and the second processed grooves 115, as illustrated in FIG. 13C.

### [Functional Layer Damage Removing Step]

Next, the controller 7 removes the first damaged regions 140 generated in the functional layer 123 in the functional layer processing step. That is, the controller 7 uses the plasma processing apparatus 4 to apply plasma processing using the first etching gas to the face sides of the processing spare grooves 117 and the second processed grooves 115. As a result, the first damaged regions 140 formed in the functional layer 123 in the functional layer processing step are removed, as illustrated in FIG. 13D.

### [Base Layer Damage Removing Step]

Next, the controller 7 removes the second damaged regions 141 generated in the base layer 122 in the functional layer processing step. That is, the controller 7 continuously uses the plasma processing apparatus 4 to perform plasma etching using the second etching gas on the face sides of the processing spare grooves 117 and the second processed grooves 115. As a result, the second damaged regions 141 formed in the base layer 122 are removed, as illustrated in FIG. 13E. Thereafter, the protective film cleaning step is carried out, and the protective film 130 is removed from the wafer 100.

Also in the present embodiment, the first damaged regions 140 generated in the functional layer 123 and the second damaged regions 141 generated in the base layer 122 are removed by plasma etching. This allows damages formed by application of a laser beam to favorably be removed from the functional layer 123 and the base layer 122, so that the flexural strength of the chips 116 that are formed by the wafer 100 being divided can be increased.

Moreover, in the present embodiment, the processing swarf removing step is carried out after the base layer processing step but before the functional layer damage removing step and the base layer damage removing step. Thus, the processing swarf 301 that has been generated in the base layer processing step can favorably be removed from the processing spare grooves 117 and the second processed grooves 115. Consequently, in the functional layer damage removing step and the base layer damage removing step, the possibility of hindrance of etching by the processing swarf 301 can be reduced, so that the first damaged regions 140 formed in the functional layer 123 and the second damaged regions 141 formed in the base layer 122 can favorably be removed.

Further, in the present embodiment, after the functional layer processing step is carried out with use of the laser processing apparatus 2, the base layer processing step and the processing swarf removing step are performed with continuous use of the laser processing apparatus 2, and thereafter, the functional layer damage removing step and the base layer damage removing step are carried out with use of the plasma processing apparatus 4. Thus, the steps of using the laser processing apparatus 2 and the steps of using the plasma processing apparatus 4 can collectively be carried out, so that the number of times of delivering the frame unit 110 including the wafer 100 between the laser processing apparatus 2 and the plasma processing apparatus 4 can be reduced. This makes it possible to reduce the length of processing time.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method for processing a wafer in which a functional layer is stacked on a base layer, the wafer processing method comprising:
a functional layer processing step of applying a laser beam to the functional layer and forming first processed grooves; and
a functional layer damage removing step of, after the functional layer processing step is carried out, performing plasma etching on face sides of the first processed grooves and removing damages formed in the functional layer processing step.

2. The wafer processing method according to claim 1, wherein
the functional layer is covered with a protective film, and
the functional layer processing step is carried out in such a manner that the protective film covering an edge of each of the first processed grooves is removed by application of the laser beam and the functional layer is exposed.

3. The wafer processing method according to claim 1, further comprising:
a base layer processing step of forming second processed grooves in the base layer.

4. The wafer processing method according to claim 3, wherein
the base layer processing step includes forming the second processed grooves by application of a laser beam to the base layer, and
the wafer processing method further includes a base layer damage removing step of, after the base layer processing step is carried out, performing plasma etching on face sides of the second processed grooves formed in the base layer and removing damages formed in the base layer processing step.

5. The wafer processing method according to claim 3, wherein
the base layer processing step includes forming the second processed grooves by application of a laser beam to the base layer, and
the wafer processing method further includes a processing swarf removing step of, after the base layer processing step is carried out but before the functional layer damage removing step is performed, applying a laser beam weaker in output power than the laser beam used in the base layer processing step to at least either the first processed grooves or the second processed grooves and subliming and removing processing swarf that has adhered to the grooves.
